(19) United States
(12) Patent Application Publication
(10) Pub. No.: US 2024/0088010 A1
(43) Pub. Date: Mar. 14, 2024

(54) SEMICONDUCTOR DEVICE AND IMAGING DEVICE

(71) Applicant: SONY SEMICONDUCTOR SOLUTIONS CORPORATION, KANAGAWA (JP)

(72) Inventors: SHINGO HAMAGUCHI, KANAGAWA (JP); TAKESHI ANDOU, KUMAMOTO (JP)

(21) Appl. No.: 18/262,932

(22) PCT Filed: Jan. 5, 2022
(86) PCT No.: PCT/JP2022/000076

§ 371 Date: Jul. 26, 2023

(30) Foreign Application Priority Data
Feb. 5, 2021 (JP) 2021-017083

(51) Int. Cl. H01L 23/498; H01L 23/00; H01L 27/146

(52) U.S. Cl. CPC H01L 23/49838; H01L 24/48; H01L 24/49; H01L 27/14636; H01L 2224/48091; H01L 2224/48227; H01L 2224/4903; H01L 2224/49175

(57) ABSTRACT

The present technology relates to a semiconductor device and an imaging device capable of achieving a configuration that does not hinder downsizing even when a plurality of terminals including terminals with a potential difference is arranged.

A chip, a wiring substrate, and a wire connecting the chip and the wiring substrate are included, and a first opening and a second opening to which the wire is connected are formed on at least one side of the wiring substrate, the one side being on a surface of the wiring substrate on which an insulating film is formed. A first terminal formed in the first opening and a second terminal formed in the second opening are arranged at positions separated by a predetermined distance in the opening. The present technology can be applied to, for example, an imaging device in which a wiring substrate and a chip are connected by a bonding wire.

### TECHNICAL FIELD

The present technology relates to a semiconductor device and an imaging device, and for example, relates to a semiconductor device and an imaging device suitable for use in downsizing a semiconductor device including a chip and a wiring substrate.

### BACKGROUND ART

It is desired to downsize a semiconductor device including a predetermined chip. For example, Patent Document 1 proposes downsizing of a semiconductor device by arranging electrode pads in a zigzag pattern.

### CITATION LIST

### Patent Document

Patent Document 1: Japanese Patent Application Laid-Open No. 5-308137

### SUMMARY OF THE INVENTION

### Problems to be Solved by the Invention

It is desired to enable arrangement of terminals with a potential difference and arrangement of many terminals with respect to the semiconductor device. It is also desired to enable downsizing even when the number of terminals increases.

The present technology has been made in view of such a situation, and an object thereof is to enable arrangement of many terminals including terminals with a potential difference, and enable downsizing.

### Solutions to Problems

A semiconductor device according to one aspect of the present technology includes a chip, a wiring substrate, and a wire connecting the chip and the wiring substrate, in which a first opening and a second opening to which the wire is connected are formed on at least one side of the wiring substrate, the one side being on a surface of the wiring substrate on which an insulating film is formed.

An imaging device according to one aspect of the present technology is an imaging device including a chip of an image sensor, a wiring substrate, and a wire connecting the chip and the wiring substrate, in which at least two openings to which the wire is connected are formed on at least one side of the wiring substrate on a surface of the wiring substrate on which an insulating film is formed.

In the semiconductor device according to one aspect of the present technology, a chip, a wiring substrate, and a wire connecting the chip and the wiring substrate are included, and a first opening and a second opening to which the wire is connected are formed on at least one side of the wiring substrate, the one side being on a surface of the wiring substrate on which an insulating film is formed.

In the imaging device according to one aspect of the present technology, a chip of an image sensor, a wiring substrate, and a wire connecting the chip and the wiring substrate are included, and at least two openings to which the wire is connected are formed on at least one side of the wiring substrate on a surface of the wiring substrate on which an insulating film is formed.

### BRIEF DESCRIPTION OF DRAWINGS

FIG. 1 is a diagram depicting a configuration of an embodiment of a semiconductor device to which the present technology is applied.

FIG. 2 is a diagram depicting a configuration example of the semiconductor device.

FIG. 3 is a diagram for describing a first embodiment regarding openings.

FIG. 4 is a diagram for describing a second embodiment regarding openings.

FIG. 5 is a diagram for describing a third embodiment regarding openings.

FIG. 6 is a diagram for describing a fourth embodiment regarding openings.

FIG. 7 is a diagram for describing a fifth embodiment regarding openings.

FIG. 8 is a diagram for describing a sixth embodiment regarding openings.

FIG. 9 is a diagram depicting a configuration example of a semiconductor package.

FIG. 10 is a diagram depicting another configuration example of the semiconductor package.

FIG. 11 is a block diagram depicting an example of schematic configuration of a vehicle control system.

FIG. 12 is a diagram of assistance in explaining an example of installation positions of an outside-vehicle information detecting section and an imaging section.

### MODES FOR CARRYING OUT THE INVENTION

Modes (which will be hereinafter referred to as embodiments) for carrying out the present technology will be described below.

<Configuration Example of Semiconductor Substrate>

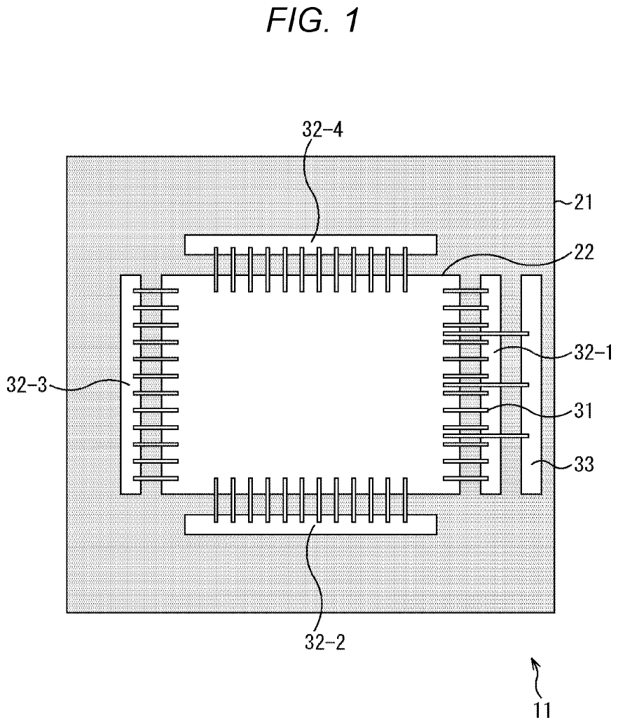

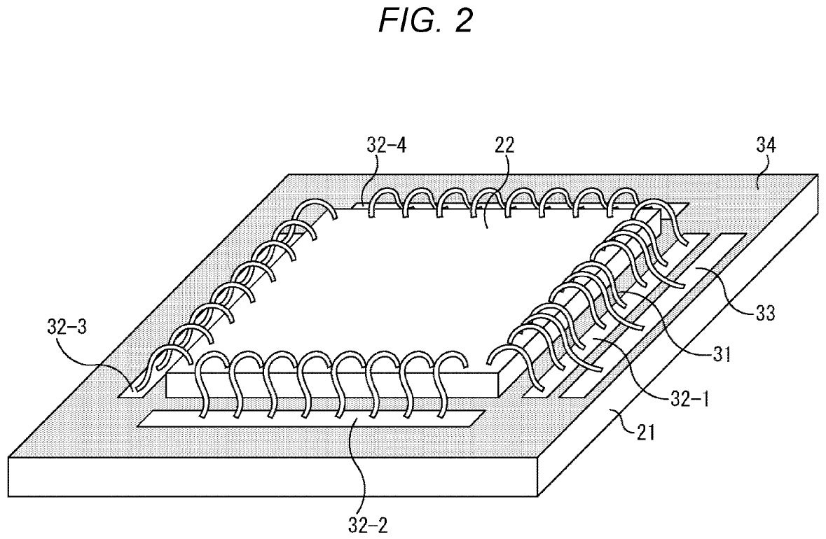

FIGS. 1 and 2 are diagrams depicting a configuration example of an embodiment of a semiconductor device to which the present technology is applied. FIG. 1 is a diagram of a semiconductor device 11 as viewed from above, and FIG. 2 is a diagram of the semiconductor device 11 as viewed from obliquely above.

The semiconductor device 11 includes a wiring substrate 21 and a chip 22. The chip 22 is disposed on the wiring substrate 21 constituting the semiconductor device 11.

A plurality of wirings is connected to the wiring substrate 21 and the chip 22. Here, the description will be continued assuming that the wirings are bonding wires. The chip 22 is electrically connected to the wiring substrate 21 by a plurality of bonding wires 31. The bonding wires 31 include a bonding wire for outputting a signal or the like processed in the chip 22 to a control section or the like in a subsequent stage provided on the wiring substrate 21, a bonding wire for supplying a power supply voltage, a grounded bonding wire, or the like.

The bonding wires 31 are provided on four sides of the chip 22. A solder resist film 34 functioning as an insulating film is formed on a surface of the wiring substrate 21. The bonding wires 31 are connected to openings 32-1 to 32-4 and an opening 33 provided in a part of the solder resist film 34.

Referring to FIG. 1, the opening 32-1 is formed on a right side of the chip 22 in the drawing, the opening 32-2 is formed on a lower side of the chip 22 in the drawing, the opening 32-3 is formed on a left side of the chip 22 in the drawing, and the opening 32-4 is formed on an upper side of the chip 22 in the drawing. The opening 33 is also formed on the right side of the chip 22 in the drawing so as to be aligned with the opening 32-1.

In the following description, the openings 32-1 to 32-4 will be simply referred to as an opening 32 in a case where it is not necessary to distinguish the openings from each other. Other parts are described in a similar manner.

The opening 32 and the opening 33 are formed on the right side of the chip 22, and bonding wires 31 are connected to each of the openings. For example, a structure may be employed in which the connection destination of the bonding wires 31 can be allocated depending on the potential in such a manner that the bonding wires 31 connected to the opening 32 are low potential terminals, and the bonding wires 31 connected to the opening 33 are high potential terminals.

Here, a low potential terminal and a high potential terminal are described to mean a terminal with a high potential difference with respect to a low potential terminal, and it is a relative potential. For example, when one potential is set to a low potential, a potential higher than the low potential is described as a high potential, and when one potential is set to a high potential, a potential lower than the high potential is described as a low potential.

In FIGS. 1 and 2, an example is depicted in which the opening 33 is formed only on the right side of the chip 22, but a configuration can be employed in which the opening is formed on other sides. That is, a configuration may be employed in which the opening 33 is formed on at least one side of the right side, the lower side, the left side, or the upper side, or formed on each of two sides, three sides, and four sides.

### First Embodiment of Opening

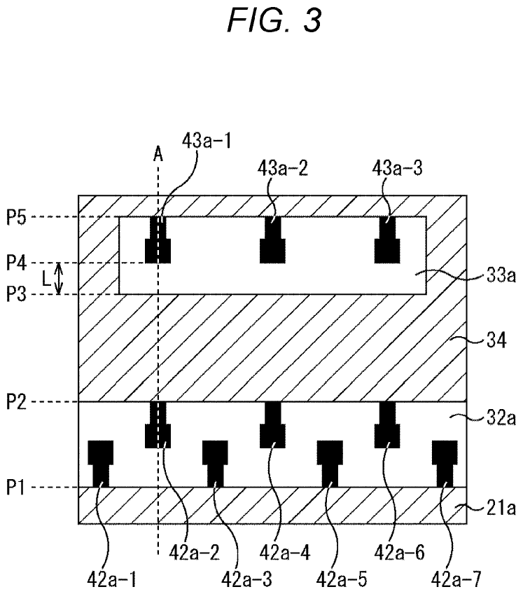

Hereinafter, configurations of the opening 32 and the opening 33 will be described. FIG. 3 is a diagram depicting a configuration example of an opening 32a and an opening 33a in the first embodiment. In the description of FIG. 3 and subsequent drawings, a region where the opening 32a and the opening 33a of a wiring substrate 21a are arranged is depicted in an enlarged manner, and the description will be given.

The opening 32a is provided in a state of being opened from a position P1 to a position P2 of the solder resist film 34 applied on the wiring substrate 21a. The opening 32a is a region where the solder resist film 34 is not formed. The opening 33a is provided in a state of being opened from the position P3 to the position P5. The positions P1 to P5 are the position P1, the position P2, a position P3, a position P4, and a position P5 in this order from the side closer to the center of the wiring substrate 21a.

Terminals 42a-1 to 42a-7 are arranged in the opening 32a. Each of the terminals 42a-1 to 42a-7 has a shape in which a lead wire is formed in a square portion. The terminals 42a-1 to 42a-7 arranged in the opening 32a are arranged in such a manner that the positions of the lead wires (the directions of the lead wires) are staggered.

The lead wire of the terminal 42a-1 is on the position P1 side, and the lead wire of the terminal 42a-2 adjacent to the terminal 42a-1 is on the position P2 side. The lead wire of the terminal 42a-3 adjacent to the terminal 42a-2 is on the position P1 side. In this manner, the terminals 42a are arranged so that the lead wires of the terminals 42a are directed in different directions between adjacent terminals.

Terminals 43a-1 to 43a-3 are arranged in the opening 33a. The terminals 43a-1 to 43a-3 each have a shape including a lead wire. The lead wire of a terminal 43a is provided on the position P5 side.

A configuration can be employed in which a bonding wire 31 set to a low potential is connected to a terminal 42a arranged in the opening 32a, and a bonding wire 31 set to a high potential is connected to a terminal 43a arranged in the opening 33a.

If the terminal to which the low potential bonding wire 31 is connected and the terminal to which the high potential bonding wire 31 is connected are arranged at close positions, there is a possibility that the terminals adversely affect each other. Therefore, normally, low potential terminals and high potential terminals (low potential terminals and terminals with a high potential difference with respect to the low potential terminals) are arranged apart from each other by a predetermined distance, and are configured so as not to affect each other. However, since it is necessary to arrange terminals having a potential difference apart from each other by a predetermined distance, that is, it is necessary to increase the distance between the terminals, the sizes of the wiring substrate 21a and the chip 22 become large, and there is a possibility that it becomes difficult to downsize the semiconductor device 11.

When the number of terminals is increased and the distance between the terminals is increased, a possibility that the size becomes larger is increased. If the size is not increased, there is a possibility that the necessary terminals cannot be completely arranged.

As in the wiring substrate 21a depicted in FIG. 3, by providing the opening 32a and the opening 33a and separating low potential terminals and terminals with a high potential difference with respect to the low potential terminals, it is possible to secure a distance between the terminals that is not affected by the potential difference. Thus, the wiring substrate 21a and the chip 22 can be downsized, and the semiconductor device 11 can be downsized. Even when the number of terminals increases, they can be downsized in a state where the arrangement of the terminals that is not affected by the potential difference is achieved.

The configuration depicted in FIG. 3 can reduce the risk of ion migration. The ion migration is, for example, a phenomenon in which when a voltage is applied in a state where the wiring substrate is installed in an environment with a large amount of moisture (humidity), the metal of the anode of a wiring pattern is ionized and moves to the opposite cathode, and is generated as metal again in the cathode. When the metal generated at the cathode grows, insulation failure may occur and a short circuit may occur between wiring patterns, and thus it is preferable that it is configured to prevent the ion migration.

Since there is a potential difference between the terminals 42a and the terminals 43a arranged in the opening 32a and the opening 33a, respectively, the terminals become terminals corresponding to the anode and the cathode described above, and there is a possibility that the ion migration occurs.

The wiring substrate 21a depicted in FIG. 3 is configured so that there is a distance L from the position P3 of the opening 33a to the position P4 of tips of the terminals 43a. By providing the opening by the distance L, the occurrence of ion migration can be suppressed.

The terminal 42a-2 and the terminal 43a-1 are arranged on the straight line A depicted in FIG. 3. A tip of the lead wire of the terminal 42a-2 is located at the position P2. The solder resist film 34 is formed from the position P2 to the position P3. The distance from the position P3 to the position P4 of a tip of the terminal 43a-1 is the distance L. In a case where it is considered excluding the position P3 from the position P2 where the solder resist film 34 is formed, in other words, in a case where only the region of the opening is considered, such a relationship can be said that the terminal 42a-2 and the terminal 43a-1 are at positions separated by the distance L.

In other words, it is configured so that, instead of being arranged directly via the solder resist film 34 at a linear distance, the terminal 42a-2 and the terminal 43a-1 are provided with an opening of the solder resist film 34, in this case, an opening from the position P3 to the position P4 of the opening 33a in the middle.

By providing the opening of the solder resist film 34 having the distance L between the terminals 42a and the terminals 43a as described above, the occurrence of ion migration can be prevented.

The present applicant has confirmed that occurrence of ion migration can be suppressed by setting the distance L to a distance satisfying the following conditional expression (1).

Distance L≥coefficient a×potential difference V\hat{ }(½) (1)

In the formula (1), the unit of the distance L is [um], and the unit of the potential difference V is [V]. In the above example, the potential difference V is a difference between the potential applied to the terminal 42a-2 and the potential applied to the terminal 43a-1. The coefficient a can be, for example, a value of 15 to 20. As indicated in Expression (1), the distance L is only required to be a value larger than a value obtained by multiplying the coefficient a by a value obtained by multiplying the potential difference V to the power of (½).

With the wiring substrate 21a in the first embodiment, it is possible to prevent the influence between low potential terminals and terminals with a high potential difference with respect to the low potential terminals, and to suppress the occurrence of ion migration. In addition, the wiring substrate 21a and the chip 22 can be downsized, and the semiconductor device 11 including them can be downsized.

### Second Embodiment of Opening

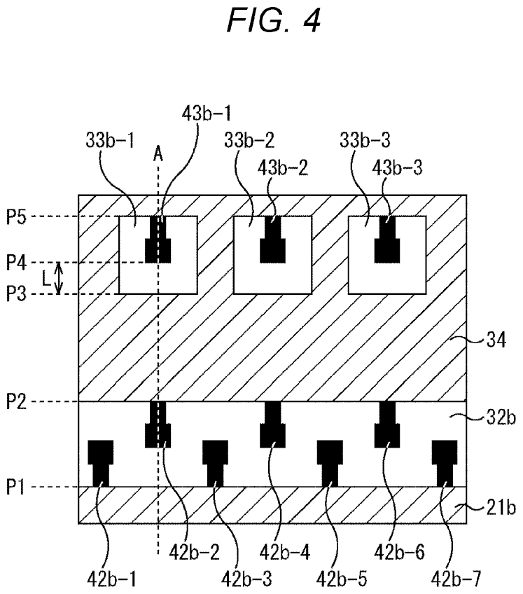

FIG. 4 is a diagram depicting a configuration example of an opening 32 and openings 33 according to the second embodiment.

An opening 32b and terminals 42b-1 to 42b-7 formed in the opening 32b have the same configurations as the opening 32a and the terminals 42a-1 to 42a-7 formed in the opening 32a in the first embodiment depicted in FIG. 3. That is, the terminals 42b-1 to 42b-7 are arranged in the opening 32b in such a manner that the lead wires are staggered.

The opening 32b depicted in FIG. 4 includes an opening 32b-1, an opening 32b-2, and an opening 32b-3, and a terminal 43b-1, a terminal 43b-2, and a terminal 43b-3 are arranged in respective openings 32b. In the configuration example depicted in FIG. 4, one opening 32b is formed for one terminal 43b.

Also in the configuration depicted in FIG. 4, for example, the terminal 42b-2 and the terminal 43b-1 are arranged at positions separated by the distance L. That is, it is configured so that, instead of being arranged directly via the solder resist film 34 at a linear distance, an opening of the solder resist film 34, in this case, an opening from the position P3 to the position P4 of the opening 33b is provided in the middle.

The terminal 42b-4 and the terminal 43b-2, and the terminal 42b-6 and the terminal 43b-3 are also arranged at positions separated by the distance L. It is configured so that, among the terminals 42b arranged in the opening 32b and the terminals 43b arranged in the openings 33b, instead of being arranged directly via the solder resist film 34 at a linear distance, the terminals close to each other by the linear distance are provided with an opening of the solder resist film 34 in the middle.

Also in a wiring substrate 21b in the second embodiment, it is possible to prevent the influence between low potential terminals and terminals with a high potential difference with respect to the low potential terminals, and to suppress the occurrence of ion migration. In addition, the wiring substrate 21b and the chip 22 can be downsized, and the semiconductor device 11 including them can be downsized.

### Third Embodiment of Opening

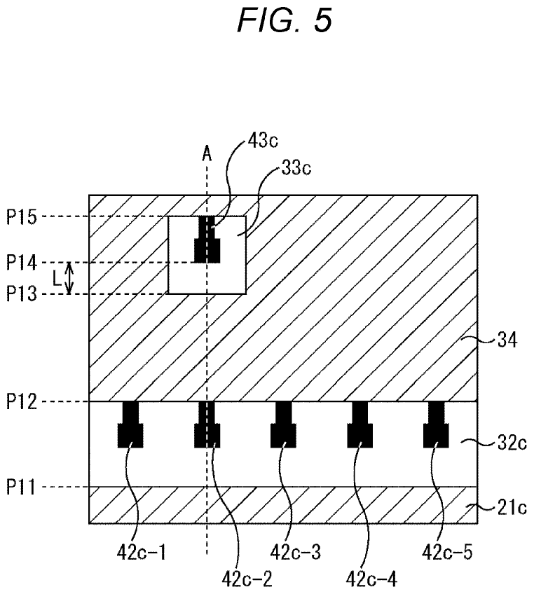

FIG. 5 is a diagram depicting a configuration example of an opening 32 and an opening 33 according to the third embodiment.

An opening 32c and terminals 42c-1 to 42c-7 formed in the opening 32c are different from the terminal 42a in the first embodiment and the terminal 42b in the second embodiment in that lead wires are arranged in the same direction. In the terminal 42c according to the third embodiment, lead wires are arranged at a position P12 on a side where the opening 33c is formed in the opening 32c opened from a position P11 to the position P12.

As described above, the lead wires of the plurality of terminals 42c arranged in the opening 32c may be arranged in the same direction.

An example in which one opening 32c is formed and one terminal 43c is arranged in a wiring substrate 21c depicted in FIG. 5 has been described. The terminals 43c is only required to be provided as many as the number of bonding wires 31 set to a high potential. As depicted in FIG. 5, in a case where there is one bonding wire 31 set to a high potential, it can also be configured so that one terminal 43c is formed and an opening 33c is formed.

By combining the third embodiment depicted in FIG. 5 and the first embodiment depicted in FIG. 3, it can also be configured so that the opening 32c is formed to be large as depicted in FIG. 3, and a plurality of terminals 43c is arranged. The third embodiment depicted in FIG. 5 and the second embodiment depicted in FIG. 4 may be combined, a plurality of openings 32c may be arranged, and one terminal 43c may be arranged in each of the openings 32c as depicted in FIG. 4.

Also in the following description, a case where one terminal 43 is formed in one opening 33 will be described, but a configuration combined with the first embodiment or the second embodiment can be employed.

Also in the configuration depicted in FIG. 5, the terminal 42c-2 and the terminal 43c are arranged at positions separated by the distance L. The distance L is a distance from a position P13 to a position P14 of the opening 33c.

Also in the configuration depicted in FIG. 5, it is configured so that, instead of being arranged directly via the solder resist film 34 at a linear distance, an opening of the solder resist film 34, in this case, an opening from the position P13 to the position P14 of the opening 33c is provided in the middle.

Also in the wiring substrate 21c in the third embodiment, it is possible to prevent the influence between low potential terminals and terminals with a high potential difference with respect to the low potential terminals, and to suppress the occurrence of ion migration. In addition, the wiring substrate 21c and the chip 22 can be downsized, and the semiconductor device 11 including them can be downsized.

### Fourth Embodiment of Opening

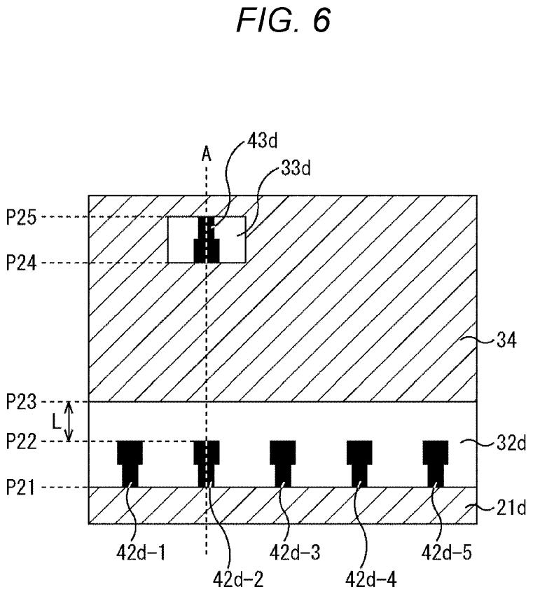

FIG. 6 is a diagram depicting a configuration example of an opening 32 and an opening 33 according to the fourth embodiment.

An opening 32d and terminals 42d-1 to 42d-7 formed in the opening 32d are similar to the terminal 42c in the third embodiment in that the lead wires are arranged in the same direction, but the directions thereof are different.

In the terminal 42d according to the fourth embodiment, lead wires are arranged at a position P21 on a side opposite to the side where an opening 33d is formed in the opening 32d opened from the position P21 to a position P23.

As described above, the lead wires of the plurality of terminals 42d arranged in the opening 32d may be arranged in the same direction.

An example in which one opening 32d is formed and one terminal 43d is arranged in a wiring substrate 21d depicted in FIG. 6 is depicted.

Also in the configuration depicted in FIG. 6, the terminal 42d-2 and the terminal 43d are arranged at positions separated by the distance L. The terminal 42d-2 and the terminal 43d are arranged on the straight line A depicted in FIG. 6.

A tip of the lead wire of the terminal 42d-2 is located at the position P21, and a tip opposite to the lead wire is located at the position P22. A distance from the position P22 of a tip of the terminal 43d-1 to the position P23 is defined as a distance L. A solder resist film 34 is formed from the position P22 to the position P23.

On the other hand, the opening 33d is opened from a position P24 to a position P25, and the terminal 43d is arranged in the opened region. A tip of the terminal 43d is located at the position P24, and a tip of the lead wire of the terminal 43d is located at a position P25. In the example depicted in FIG. 6, the opening 33d and the terminal 43d are formed to have sizes in which the width of the opening 33d and the length of the terminal 43d match each other.

In the example depicted in FIG. 6, the distance L is provided on the opening 32d side. In a case where it is considered excluding the position P24 from the position P23 where the solder resist film 34 is formed, in other words, in a case where only the regions of the opening 32d and the opening 33d are considered, the terminal 42d-2 and the terminal 43d are separated from each other by the distance L.

In other words, it is configured so that, instead of being arranged directly via the solder resist film 34 at a linear distance, the terminal 42d-2 and the terminal 43d are provided with an opening of the solder resist film 34, in this case, an opening from the position P22 to the position P23 of the opening 32d in the middle.

Also in the wiring substrate 21d in the fourth embodiment, it is possible to prevent the influence between low potential terminals and terminals with a high potential difference with respect to the low potential terminals, and to suppress the occurrence of ion migration. In addition, the wiring substrate 21d and the chip 22 can be downsized, and the semiconductor device 11 including them can be downsized.

### Fifth Embodiment of Opening

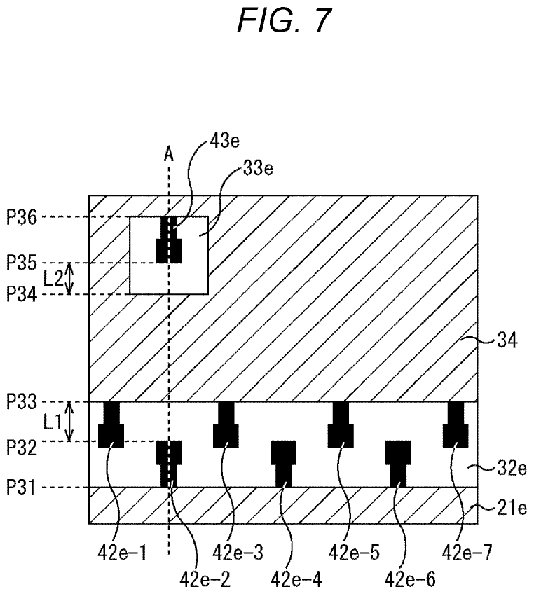

FIG. 7 is a diagram depicting a configuration example of an opening 32 and an opening 33 according to the fifth embodiment.

An opening 32e and terminals 42e-1 to 42e-7 formed in the opening 32e are arranged in such a manner that lead wires are staggered.

Also in the configuration depicted in FIG. 7, for example, the terminal 42e-2 and a terminal 43e are arranged at positions separated by the distance L. The terminal 42e-2 and the terminal 43e are arranged on the straight line A depicted in FIG. 7. A tip of the lead wire of the terminal 42e-2 is located at a position P31, and a tip opposite to the lead wire is located at a position P32. The distance from the position P32 of the tip of the terminal 42e-2 to a position P33 is the distance L1. The solder resist film 34 is formed from the position P33 to a position P34.

On the other hand, an opening 33e is opened from the position P34 to a position P36. A tip of the terminal 43e is located at a position P35, and a tip of the lead wire of the terminal 43e is located at the position P36. The distance from the position P35 of the tip of the terminal 43e to the position P34 is a distance L2.

In the example depicted in FIG. 7, the distance L1 is provided on the opening 32e side, and the distance L2 is provided on the opening 33e side. The distance L corresponding to the distance L in the above-described embodiment is a distance obtained by adding the distance L1 and the distance L2. That is, distance L=distance L1+distance L2.

Also in the example depicted in FIG. 7, the distance L is provided. In a case where it is considered excluding the position P34 from the position P33 where the solder resist film 34 is formed, in other words, in a case where only the regions of the opening 32e and the opening 33e are considered, the terminal 42e-2 and the terminal 43d are arranged at positions separated by the distance L.

In other words, it is configured so that, instead of being arranged directly via the solder resist film 34 at a linear distance, the terminal 42e-2 and the terminal 43e are provided with an opening of the solder resist film 34, in this case, an opening obtained by adding an opening from the position P32 to the position P33 of the opening 32e and an opening from the position P34 to the position P35 of the opening 33e in the middle.

Also in a wiring substrate 21e in the fifth embodiment, it is possible to prevent the influence between low potential terminals and terminals with a high potential difference with respect to the low potential terminals, and to suppress the occurrence of ion migration. In addition, the wiring substrate 21e and the chip 22 can be downsized, and the semiconductor device 11 including them can be downsized.

### Sixth Embodiment of Opening

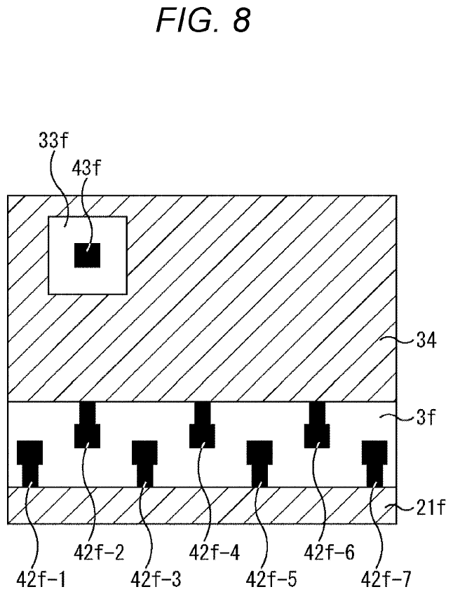

FIG. 8 is a diagram depicting a configuration example of an opening 32 and an opening 33 according to the sixth embodiment.

Although the terminal 42 and the terminal 43 in the first to fifth embodiments have been described by taking the terminal in which the lead wire is formed as an example, a terminal in which the lead wire is not formed can also be applied to the present embodiment. In the example depicted in FIG. 8, a terminal 43f is a terminal having no lead wire.

The terminal 43f is formed in a square shape in a central portion of an opening 33f. The terminal 43f has no portion in contact with the solder resist film 34, and the entire periphery of the terminal 43f is a region where the solder resist film 34 is opened. Such a terminal 43f can be applied to the terminals 43 in the first to fifth embodiments.

In the example depicted in FIG. 8, terminals 42f-1 to 42f-7 arranged in an opening 32f are depicted by exemplifying terminals in which lead wires are formed, but the terminals 42f-1 to 42f-7 may also have a configuration similar to that of the terminal 43f. In addition, as with the terminal 43f, a shape without a lead wire can be applied to the terminals 42 in the first to fifth embodiments.

<Configuration of Imaging Element>

The semiconductor device 11 including any of the wiring substrates 21 in the first to eighth embodiments can be applied to an imaging element.

Reference is made again to FIG. 1. The semiconductor device 11 includes the wiring substrate 21 and the chip 22. The chip 22 is disposed on the wiring substrate 21 constituting the semiconductor device 11. By using the chip 22 as an image sensor (hereinafter described as an image sensor 22), the semiconductor device 11 can be used as an imaging element.

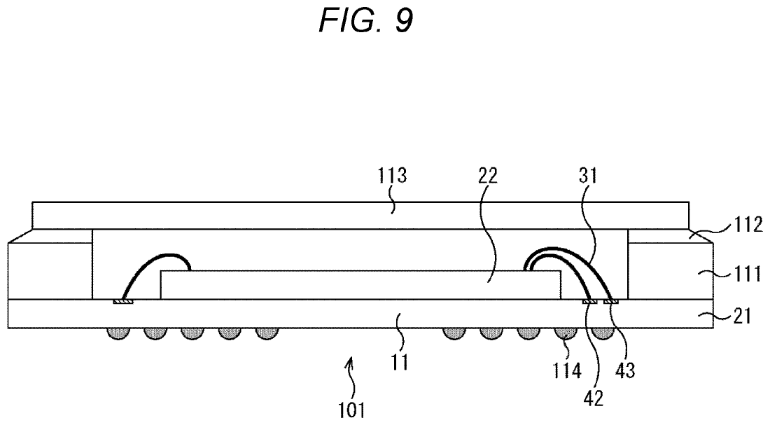

The image sensor 22 can be a complementary metal oxide semiconductor (CMOS) image sensor or a charge coupled device (CCD) image sensor. The semiconductor device 11 including the image sensor 22 can also be configured as a semiconductor package (PKG). FIG. 9 is a cross-sectional view depicting a configuration example of a semiconductor package 101 having a hollow structure.

The image sensor 22 disposed on the wiring substrate 21 is at a position included in a spacer 111. The semiconductor device 11 including the wiring substrate 21 and the image sensor 22 is the semiconductor device 11 to which any one of the first to eighth embodiments is applied.

The spacer 111 is disposed on the wiring substrate 21. A cover glass 113 is fixed onto the spacer 111 with an adhesive 112 interposed therebetween. The image sensor 22 is disposed in a space surrounded by the wiring substrate 21, the spacer 111, and the cover glass 113.

Solder balls 114 are formed below the wiring substrate 21. The solder balls 114 are connected to the image sensor 22 via the bonding wires 31. The solder balls 114 are used when it is connected to a substrate that is not depicted or the like.

As described above, the present technology can be applied to an imaging device, and can also be applied to a case where the imaging device is configured as a semiconductor package. An organic substrate may be used in a semiconductor package, but ion migration may occur in the organic substrate, and unless some measures are taken, ion migration may occur, and malfunction may occur.

However, as described above, according to the present embodiment, since it is a structure in which the occurrence of ion migration can be suppressed, the occurrence of ion migration can be suppressed even in a case where an organic substrate is used.

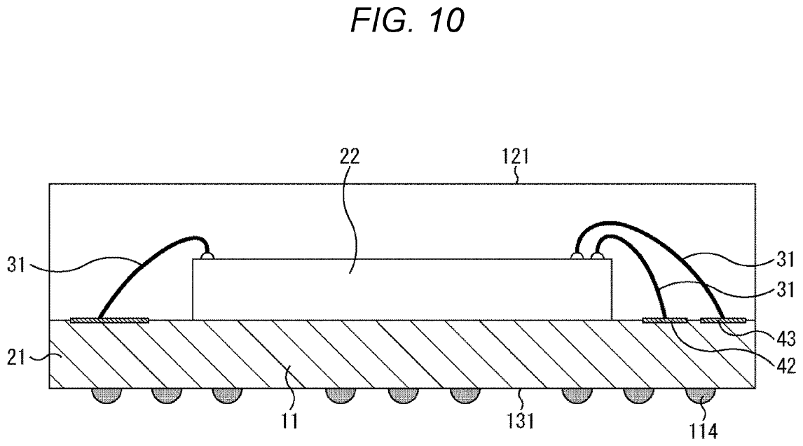

FIG. 9 depicts a case where the present technology is applied to a semiconductor package having a hollow structure, but the present technology can also be applied to a resin-sealed semiconductor package. FIG. 10 is a diagram depicting a configuration example in a case where the present technology is applied to a resin-sealed semiconductor package.

A semiconductor package 131 depicted in FIG. 10 is different from the semiconductor package 101 depicted in FIG. 9 in that the periphery of the image sensor 22 arranged on the wiring substrate 21 is filled with a resin 121, but is configured similarly in other points.

By applying the present technology also to the resin-sealed semiconductor package 131, it is possible to achieve an imaging device in which occurrence of ion migration is suppressed.

According to the present technology, even in a semiconductor package using an organic substrate on which a chip having a high potential difference is mounted, predetermined quality can be satisfied. For example, in a semiconductor package mounted on a vehicle, terminals with a high potential difference are arranged, the number of terminals tends to increase, and the environment in which the semiconductor package is used may be high temperature and high humidity. With a semiconductor package including the semiconductor device 11 to which the present technology is applied, quality required for such a semiconductor package mounted on a vehicle can be satisfied.

According to the present technology, the semiconductor device 11 can be downsized. The semiconductor package including the semiconductor device 11 can also be downsized.

<Example of Application to Mobile Body>

The technology according to the present disclosure (the present technology) can be applied to various products. For example, the technology of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

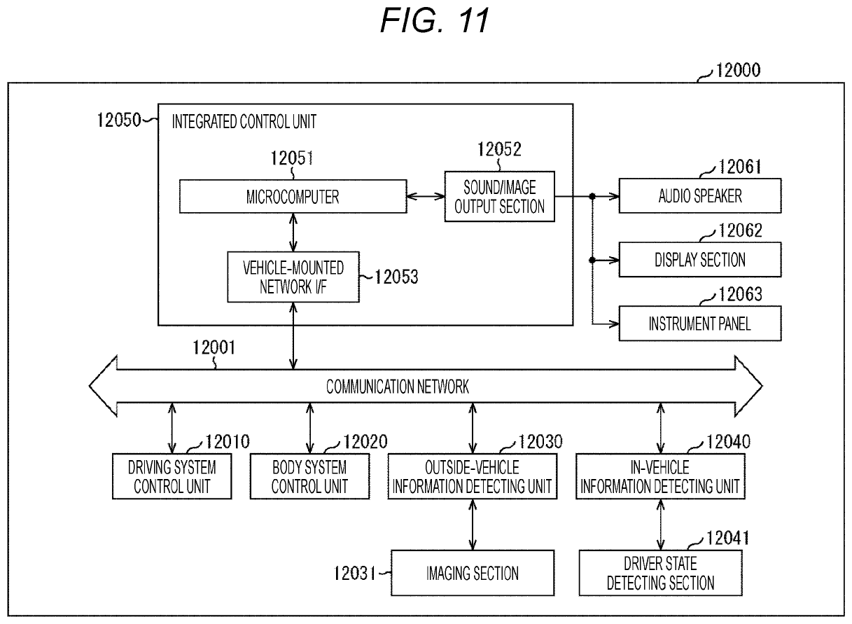

FIG. 11 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 11, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

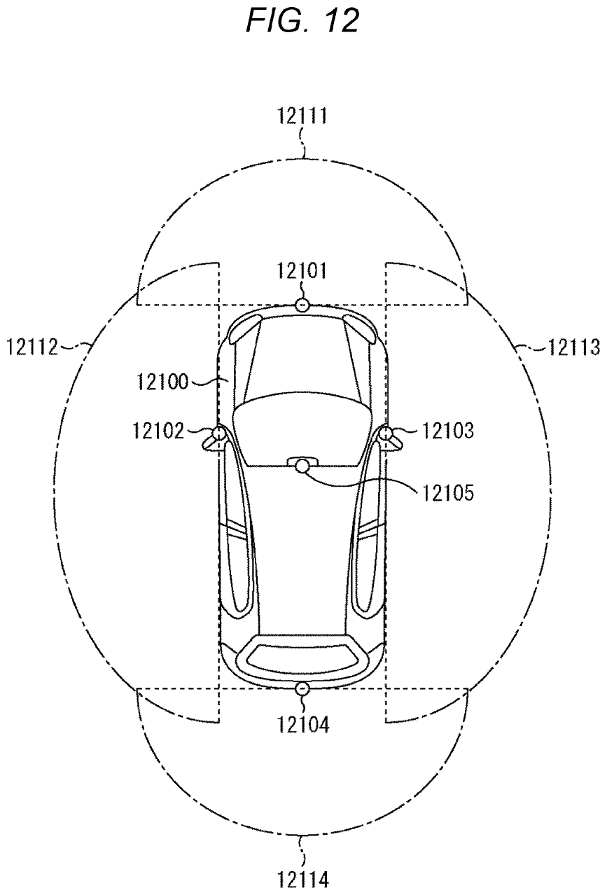

FIG. 12 is a diagram depicting an example of the installation position of the imaging section 12031.

In FIG. 12, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 12 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that the effects described in the present specification are merely illustrative and not restrictive, and other effects may be provided.

Note that embodiments of the present technology are not limited to the above embodiments, and various modifications may be made to them without departing from the scope of the present technology.

Note that the present technology may have the following configurations.

(1)

A semiconductor device including:
a chip;
a wiring substrate; and
a wire connecting the chip and the wiring substrate, in which
a first opening and a second opening to which the wire is connected are formed on at least one side of the wiring substrate, the one side being on a surface of the wiring substrate on which an insulating film is formed.

(2)

The semiconductor device according to (1) above, in which
a first terminal formed in the first opening and a second terminal formed in the second opening are arranged at positions separated by a predetermined distance in the opening.

(3)

The semiconductor device according to (2) above, in which
on a straight line on which the first terminal and the second terminal are arranged, a distance between the first terminal and the second terminal is separated by the predetermined distance except for a distance of the insulating film between the first terminal and the second terminal.

(4)

The semiconductor device according to (2) or (3) above, in which
the wire set to a low potential is connected to the first terminal, and the wire set to a high potential with respect to the low potential is connected to the second terminal.

(5)

The semiconductor device according to (4) above, in which
the predetermined distance is expressed by the following formula

Distance=coefficient×potential difference\hat{ }(½)
using a potential difference between the low potential and the high potential.

(6)

The semiconductor device according to (5) above, in which
the coefficient is 15 to 20.

(7)

The semiconductor device according to any one of (2) to (6) above, in which
the predetermined distance is provided in the second opening.

(8)

The semiconductor device according to any one of (2) to (6) above, in which
the predetermined distance is provided in the first opening.

(9)

The semiconductor device according to any one of (2) to (6) above, in which
the predetermined distance is a distance obtained by adding a first distance provided in the first opening and a second distance provided in the second opening.

(10)

The semiconductor device according to any one of (2) to (9) above, in which
the first terminal includes lead wires, and is arranged in the first opening in such a manner that directions of the lead wires are staggered.

(11)

The semiconductor device according to any one of (2) to (9) above, in which
the first terminal includes a lead wire, and is arranged in the first opening in such a manner that a direction of the lead wire is a direction in which the second opening is located.

(12)

The semiconductor device according to any one of (2) to (9) above, in which
the first terminal includes a lead wire, and is arranged in the first opening in such a manner that a direction of the lead wire is opposite to a direction in which the second opening is present.

(13)

The semiconductor device according to any one of (2) to (12) above, in which
the second terminal is formed as a single terminal in the second opening.

(14)

The semiconductor device according to any one of (2) to (12) above, in which
a plurality of the second terminals is formed in the second opening.

(15)

The semiconductor device according to any one of (1) to (14) above, in which
the chip is an image sensor.

(16)

An imaging device including:
a chip of an image sensor;
a wiring substrate; and
a wire connecting the chip and the wiring substrate, in which
at least two openings to which the wire is connected are formed on at least one side of the wiring substrate, the one side being on a surface of the wiring substrate on which an insulating film is formed.

(17)

The imaging device according to (16) above, in which
the imaging device is a semiconductor package having a hollow structure.

(18)

The imaging device according to (16) above, in which
the imaging device is a semiconductor package in which the chip is a resin-sealed.

### REFERENCE SIGNS LIST

11 Semiconductor device
21 Wiring substrate
22 Chip
31 Bonding wire
32 Opening
33 Opening
34 Solder resist film
42 Terminal
43 Terminal
101 Semiconductor package
111 Spacer
112 Adhesive
113 Cover glass
114 Solder ball
131 Semiconductor package

1. A semiconductor device, comprising:
a chip;
a wiring substrate; and
a wire connecting the chip and the wiring substrate, wherein
a first opening and a second opening to which the wire is connected are formed on at least one side of the wiring substrate, the one side being on a surface of the wiring substrate on which an insulating film is formed.

2. The semiconductor device according to claim 1, wherein
a first terminal formed in the first opening and a second terminal formed in the second opening are arranged at positions separated by a predetermined distance in the opening.

3. The semiconductor device according to claim 2, wherein
on a straight line on which the first terminal and the second terminal are arranged, a distance between the first terminal and the second terminal is separated by the predetermined distance except for a distance of the insulating film between the first terminal and the second terminal.

4. The semiconductor device according to claim 2, wherein
the wire set to a low potential is connected to the first terminal, and the wire set to a high potential with respect to the low potential is connected to the second terminal.

5. The semiconductor device according to claim 4, wherein
the predetermined distance is expressed by the following formula
Distance=coefficient×potential difference\hat{ }(½)
using a potential difference between the low potential and the high potential.

6. The semiconductor device according to claim 5, wherein
the coefficient is 15 to 20.

7. The semiconductor device according to claim 2, wherein
the predetermined distance is provided in the second opening.

8. The semiconductor device according to claim 2, wherein
the predetermined distance is provided in the first opening.

9. The semiconductor device according to claim 2, wherein
the predetermined distance is a distance obtained by adding a first distance provided in the first opening and a second distance provided in the second opening.

10. The semiconductor device according to claim 2, wherein
the first terminal includes lead wires, and is arranged in the first opening in such a manner that directions of the lead wires are staggered.

11. The semiconductor device according to claim 2, wherein
the first terminal includes a lead wire, and is arranged in the first opening in such a manner that a direction of the lead wire is a direction in which the second opening is located.

12. The semiconductor device according to claim 2, wherein
the first terminal includes a lead wire, and is arranged in the first opening in such a manner that a direction of the lead wire is opposite to a direction in which the second opening is present.

13. The semiconductor device according to claim 2, wherein
the second terminal is formed as a single terminal in the second opening.

14. The semiconductor device according to claim 2, wherein
a plurality of the second terminals is formed in the second opening.

15. The semiconductor device according to claim 1, wherein
the chip is an image sensor.

16. An imaging device comprising:
a chip of an image sensor;
a wiring substrate; and
a wire connecting the chip and the wiring substrate, wherein
at least two openings to which the wire is connected are formed on at least one side of the wiring substrate, the one side being on a surface of the wiring substrate on which an insulating film is formed.

17. The imaging device according to claim 16, wherein
the imaging device is a semiconductor package having a hollow structure.

18. The imaging device according to claim 16, wherein
the imaging device is a semiconductor package in which the chip is a resin-sealed.
